(19) United States
(12) Patent Application Publication
(10) Pub. No.: US 2002/0197876 A1
(43) Pub. Date: Dec. 26, 2002

(54) Single-chamber dual-temperature photoresist dry strip

(75) Inventor: Yu-Cheng Liu, Shala Taichung County (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 09/881,231

(22) Filed: Jun. 13, 2001

(51) Int. Cl. H01L 21/302; H01L 21/461

(52) U.S. Cl. 438/706

(57) ABSTRACT

Dual-temperature photoresist dry stripping within a single chamber is disclosed. A semiconductor wafer is subjected to a first dry strip at a first, lower temperature, and then is subjected to a second dry strip at a second, higher temperature. Both dry strips are performed in the same chamber. The first and the second temperatures may be substantially 165° C. and 250° C., respectively. Both dry strips may be performed in a C₂F₆ and O₂ gas mixture, such as at a substantially 2% ratio of the former to the latter. The disclosed dry stripping prevents substrate peeling.

### FIELD OF THE INVENTION

This invention relates generally to the removal of photoresist in semiconductor processing. More specifically, the invention relates to such removal by a dry strip process in a single chamber, where the semiconductor wafer is first subjected to a first, lower temperature, and then to a second, higher temperature.

### BACKGROUND OF THE INVENTION

There are four basic operations in semiconductor processing, layering, patterning, doping, and heat treatments. Layering is the operation used to add thin layers to the surface of a semiconductor wafer. Patterning is the series of steps that results in the removal of selected portions of the layers added in layering. Doping is the process that puts specific amounts of dopants in the wafer surface through openings in the surface layers. Finally, heat treatments are the operations in which the wafer is heated and cooled to achieve specific results, where no additional material is added or removed from the wafer.

Of these four basic operations, patterning is typically the most critical. The patterning operation creates the surface parts of the devices that make up a circuit on the semiconductor wafer. The operation sets the critical dimensions of these devices. Errors during patterning can cause distorted or misplaced defects that result in changes in the electrical function of the device, as well as device defects.

The patterning process is also known by the terms photomasking, masking, photolithography, and microlithography. The process is a multi-step process similar to photography or stenciling. The required pattern is first formed in photomasks and transferred into the surface layers of the semiconductor wafer. This is shown by reference to FIGS. 1A and 1B. In FIG. 1A, the wafer 100 has an oxide layer 102 and a photoresist layer 104. A mask 106 is precisely aligned over the wafer 100, and the photoresist 104 is exposed, as indicated by the arrows 108. This causes the exposure of the photoresist layer 104, except for the part 110 that was masked by the part 112 of the mask 106. In FIG. 1B, the unexposed part 110 of the photoresist layer 104 is removed, creating a hole 114 in the photoresist layer 104.

Next, a second transfer takes place from the photoresist layer 104 into the oxide layer 102. This is shown in FIG. 1C, where the hole 114 extends through both the photoresist layer 104 and the oxide layer 102. The transfer occurs when etchants remove the portion of the wafer's top layer that is not covered by photoresist. The chemistry of photoresists is such that they do not dissolve, or dissolve very slowly, in the chemical etching solutions. Finally, the photoresist layer 104 is removed, as shown in FIG. 1D, such that only the wafer 100 and the oxide layer 102 with the hole 114 remains.

The removal of the photoresist layer can be accomplished by either wet or dry etching. Wet etching refers to the use of wet chemical processing to remove the photoresist. The chemicals are placed on the surface of the wafer, or the wafer itself is submerged in the chemicals. Dry etching refers to the use of plasma stripping, using a gas such as oxygen (O₂), C₂F₆ and O₂, or another gas. Whereas wet etching is a low-temperature process, dry etching is typically a high-temperature process.

One type of dry etching process is shown in FIG. 2. Within the chamber 200, a semiconductor wafer 202 sits on a number of pins 208, 210, and 212, such that the wafer rests against a heater block 216. This position of the wafer 202 resting against the block 216 is referred to as the pin down position. Gas is introduced at insertion point 206, where the showerhead 204 sprays the gas onto the plasma 218, which is situated within the grounded grid 214. The plasma 218 energizes the gas to a high-energy state, which in turn oxidizes the resist components to gases that are removed from the chamber 200 by a vacuum pump (not shown in FIG. 2). Dry etching is advantageous to wet etching for resist stripping because it eliminates the use of wet hoods and the handling of chemicals.

However, dry etching is disadvantageous because it can affect the underlying wafer from which resist is being stripped. For instance, substrate peeling can occur. Substrate peeling can occur when there is a film or coating, such as gold, chromium, etc., on the silicon substrate, such that the coating peels away from the substrate. This is shown in FIG. 3, where the coating 304 is peeling away from the underlying substrate 302. Furthermore, substrate peeling can occur when part of the substrate itself peels away. This is also shown in FIG. 3, where the top part 304 of the substrate is peeling away from the rest of the substrate 302, although in actuality the peeling is likely to be less smooth than is shown in the figure. Such substrate peeling can occur where the substrate is amorphous silicon, for example.

Substrate peeling has been found to occur where the dry etching is conducted in chambers from Mattson Technology, of Fremont, Calif. under the following conditions. The gas used in the chamber is C₂F₆ and O₂, in a ratio of 2% of the former to the latter, and the temperature is 250° C. Dry etching conducted in other types of chambers, such as those available from Omega Semiconductor, of Malaysia, have other problems. For instance, reducing the C₂F₆ to O₂ ratio to 0.5% at a lower temperature still causes a high defect rate, as well as substrate peeling, in chambers from Omega.

One solution to this problem that has been found is to two use two different types of chambers. As an example, a low temperature dry strip may be performed in a chamber from Omega, followed by a high temperature dry strip in a chamber from Mattson. This two-chamber process avoids substrate peeling, but is not commercially feasible, primarily because of cost and time constraints.

There is a need to overcome these and other disadvantages of the prior art. Specifically, there is a need for dry stripping of photoresist that does not cause substrate peeling or other problems. Furthermore, there is a need for such dry stripping without the use of two separate chambers, such that the dry stripping is commercially feasible. For these and other reasons, therefore, there is a need for the present invention.

### SUMMARY OF THE INVENTION

The invention relates to dual-temperature photoresist dry stripping within a single chamber. A semiconductor wafer is subjected to a first dry strip at a first, lower temperature, and then is subjected to a second dry strip at a second, higher temperature. Both dry strips are performed in the same chamber. The chamber may be such that in the first dry strip, the wafer is in a pin up position above a heater block, resting on pins movably extending through the heater block. In the second dry strip, the wafer is in a pin down position where it rests on at least the heater block.

The first dry strip reduces thermal stressing of the semiconductor wafer, whereas the second dry strip provides for effective resist stripping. The first and the second temperatures may be substantially 165° C. and 250° C., respectively. Both dry strips may be performed in a C₂F₆ and O₂ gas mixture, such as at a substantially 2% ratio of the former to the latter. Plasma oxidizes this inserted gas in the chamber to remove the photoresist from the semiconductor wafer. The chamber may be one available from Mattson.

The two-stage photoresist dry strip process of the invention provides for advantages not found within the prior art. Significantly, the dry stripping of the invention avoids substrate peeling. Because the process is conducted entirely in a single chamber, it is also commercially feasible from cost and time standpoints. Still other advantages, aspects, and embodiments of the invention will become apparent by reading the detailed description that follows, and by referencing the attached drawings.

### BRIEF DESCRIPTION OF THE DRAWINGS

FIGS. 1A, 1B, 1C, and 1D are diagrams illustrating the general patterning process performed in semiconductor manufacture.

FIG. 2 is a diagram showing a prior art single-stage dry strip process that can cause substrate peeling.

FIG. 3 is a diagram illustrating substrate peeling.

FIG. 4 is a flowchart of the two-stage single-chamber dry strip process of the invention.

FIGS. 5A and 5B are diagrams showing the first and the second dry strip stages, respectively, in one embodiment of the invention.

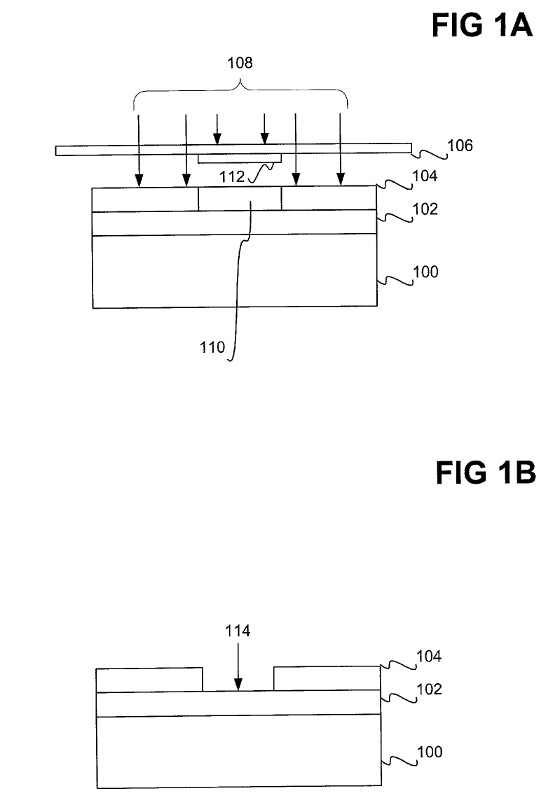

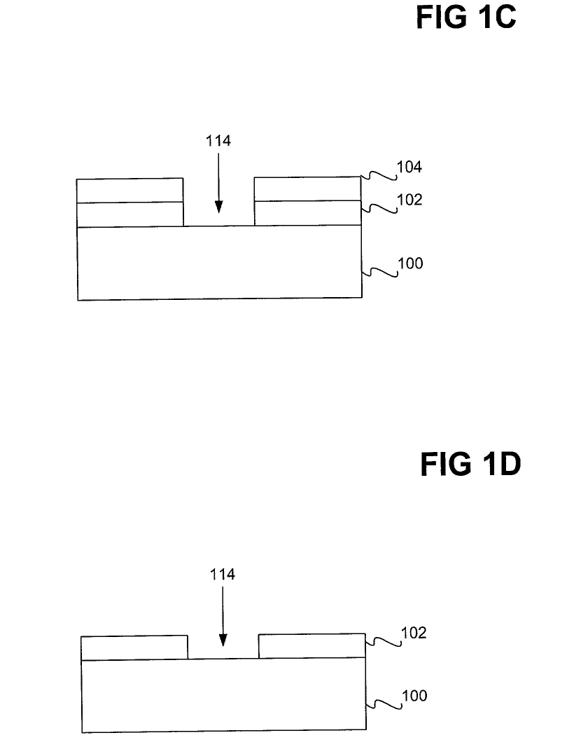

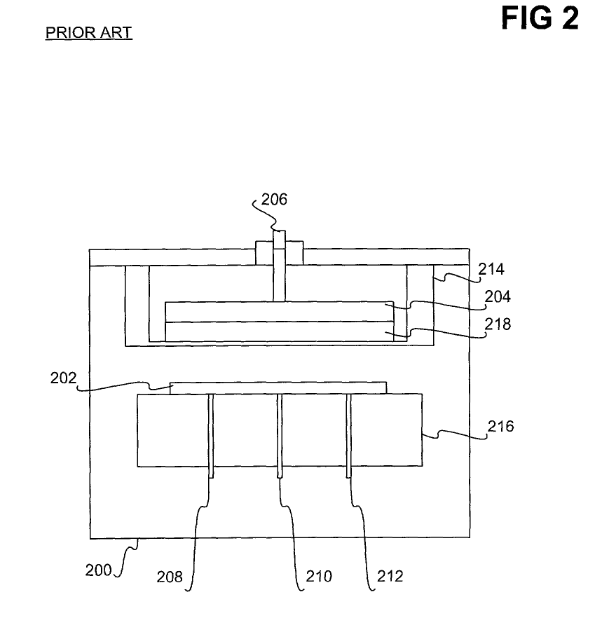

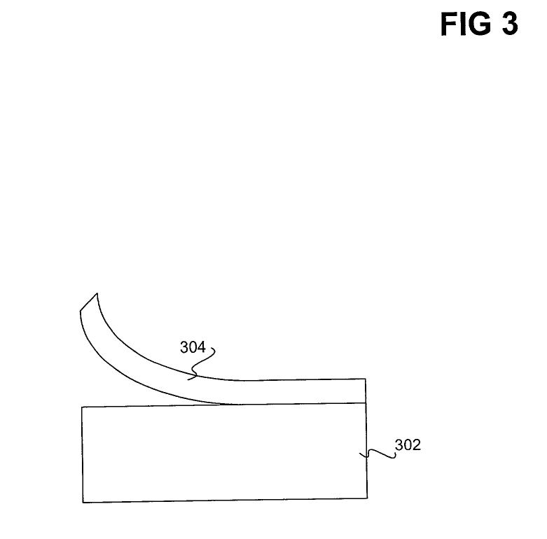

### DETAILED DESCRIPTION OF THE INVENTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

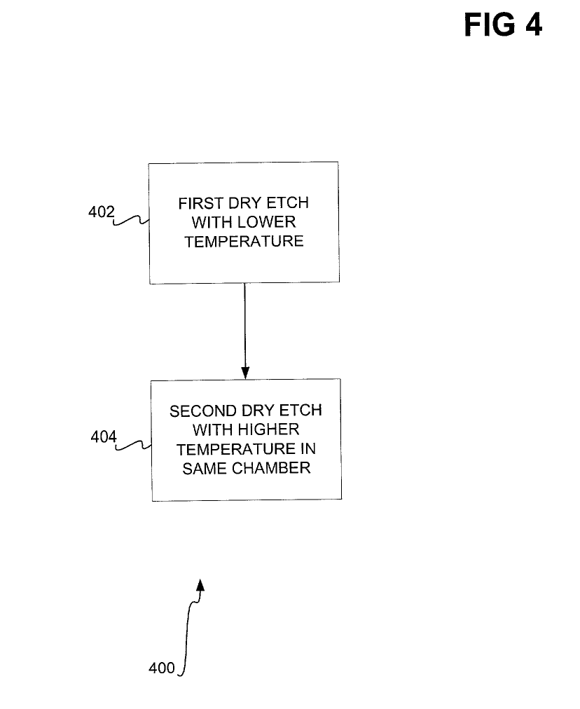

FIG. 4 is a flowchart of a method 400 showing the overall dry strip process of the invention. A first dry strip is performed at a first, lower temperature (402). A second dry strip is then performed, at a second, higher temperature (404). Each of the dry strips is performed in the same chamber, such as a chamber from Omega, and preferably a chamber from Mattson. The lower temperature is preferably 165° C., whereas the higher temperature is preferably 250° C. The lower temperature of the first dry strip reduces thermal stress between the photoresist and the wafer substrate, which may be amorphous silicon. Alternatively, the wafer may be other than amorphous silicon. For example, the wafer may have a silicon substrate with a film or coating, such as gold, chromium, etc., thereon. The higher temperature of the second dry strip completes the dry strip process of the invention effectively, without substrate peeling of the wafer. In one embodiment, each of the first and second dry strips lasts for between 50 and 150 seconds.

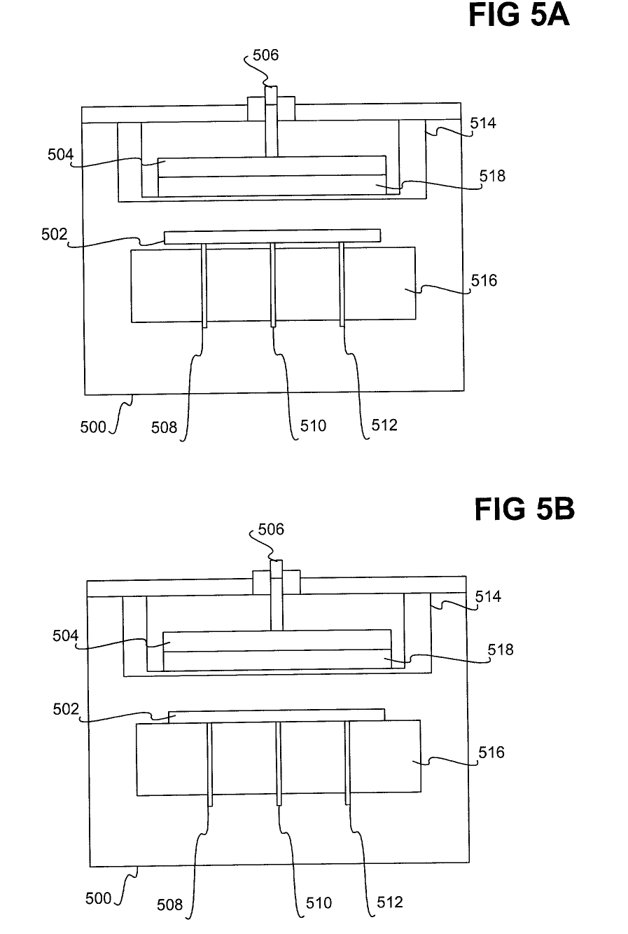

FIG. 5A is a diagram showing the first dry strip according to an embodiment of the invention. Within the chamber 500, a semiconductor wafer 502 sits on a number of pins 508, 510, and 512. The pins 508, 510, and 512 are vertically movable within the heater block 516. As shown in FIG. 5A, the wafer 502 is in the pin up position, meaning that the ends of the pins 508, 510, and 512 extend above the top surface of the heater block 516, such that the wafer 502 does not touch the heater block 516. Gas is introduced at insertion point 506, where the showerhead 504 sprays the gas onto the plasma 518, which is situated within the grounded grid 514. The plasma 518 energizes the gas to a high-energy state, which in turn oxidizes the resist components to gases that are removed from the chamber 500 by a vacuum pump (not shown in FIG. 5A). The gas may be oxygen (O₂), a C₂F₆ and O₂ mixture, or another type of gas. Preferably, the gas is a C₂F₆ and O₂ mixture with a ratio of 2% of the former to the latter.

FIG. 5B is a diagram showing the second dry strip according to an embodiment of the invention. Within the chamber 500, the semiconductor wafer 502 sits on the pins 508, 510, and 512. As shown in FIG. 5B, the wafer 502 is in the pin down position, meaning that the ends of the pins 508, 510, and 512 are desirably flush with the top surface of the heater block 516, or at least do not extend above this surface. The wafer 502 thus touches, or rests upon, the heater block 516. Gas is again introduced at the insertion point 506, and the showerhead sprays the gas onto the plasma 518, which is situated within the grid 514. The plasma 518 energizes the gas, oxidizing the photoresist to gases that are removed from the chamber 500. Preferably, the gas in the second dry strip is the same as that used in the first dry strip.

Thermal stress analysis can be employed to demonstrate why substrate peeling does not occur with the invention. In general,

$$β = \frac{1}{V} {( \frac{δ V}{δ T} )}_{P} , \qquad ( 1 )$$

where β is the thermal expansion coefficient, V is volume, and T is temperature. From equation (1), then,

ΔVαΔTασ (2)

where σ is thermal stress. Assuming that the wafer temperature is 30° C. before the dry strip process is performed, and the wafer temperature is 250° C. during prior art dry strip, the thermal stress when employing a one-stage prior art dry strip is referred to as σ.

The invention uses two stages, however. In the first stage, the wafer rises in temperature from 30° C. to 165° C., resulting in a thermal stress after the first stage of σ₁=0.61 σ, because

$$\frac{250 - 30}{165 - 30} = \frac{σ}{{σ}_{1}} . \qquad ( 3 )$$

In the second stage, the wafer rises in temperature from 165° C. to 250° C., resulting in a thermal stress after the second stage of σ₂=0.62σ₁=0.38σ, because

$$\frac{250 - 30}{250 - 165} = \frac{σ}{{σ}_{2}} . \qquad ( 4 )$$

In other words, the thermal stress of the wafer after the two-stage dry strip process of the invention is 38% of what the thermal stress of the wafer would be if the one-stage dry strip process of the prior art had been used. This significant reduction in thermal stress at least in part prevents substrate peeling of the semiconductor wafer.

It is noted that, although specific embodiments have been illustrated and described herein, it will be appreciated by those of ordinary skill in the art that any arrangement is calculated to achieve the same purpose may be substituted for the specific embodiments shown. This application is intended to cover any adaptations or variations of the present invention. Therefore, it is manifestly intended that this invention be limited only by the claims and equivalents thereof.

What is claimed is:

1. A method to dry strip a semiconductor wafer without substrate peeling, comprising:
subjecting the semiconductor wafer to a first dry strip at a first temperature in a chamber, the semiconductor wafer in a pin up position within the chamber in the first dry strip; and,
subjecting the semiconductor wafer to a second dry strip at a second temperature in the chamber, the second temperature higher than the first temperature, the semiconductor wafer in a pin down position within the chamber in the second dry strip.

2. The method of claim 1, wherein the first temperature is substantially 165° C.

3. The method of claim 1, wherein the second temperature is substantially 250° C.

4. The method of claim 1, wherein the first and the second dry strips are performed in a C₂F₆ and O₂ gas mixture.

5. The method of claim 4, wherein the C₂F₆ and O₂ gas mixture has a substantially 2% ratio.

6. The method of claim 1, wherein the first and the second dry strips are performed by plasma oxidizing an inserted gas to remove photoresist from the semiconductor wafer without substrate peeling.

7. The method of claim 1, wherein the chamber comprises a heater block and a plurality of pins vertically movable therewithin, such that the pin up position within the chamber is where the semiconductor wafer rests upon ends of the pins above the heater block.

8. The method of claim 1, wherein the chamber comprises a heater block and a plurality of pins vertically movable therewithin, such that the pin down position within the chamber is where the semiconductor wafer rests upon at least the heater block.

9. A method to dry strip a semiconductor wafer comprising:
subjecting the semiconductor wafer to a first dry strip at a first temperature in a chamber, the semiconductor wafer in a pin up position within the chamber in the first dry strip, the chamber comprising a heater block and a plurality of pins vertically movable therewithin, such that the pin up position within the chamber is where the semiconductor wafer rests upon ends of the pins above the heater block; and,
subjecting the semiconductor wafer to a second dry strip at a second temperature in the chamber, the second temperature higher than the first temperature, the semiconductor wafer in a pin down position within the chamber in the second dry strip, such that the pin down position within the chamber is where the semiconductor wafer rests upon at least the heater block.

10. The method of claim 9, wherein the first temperature is substantially 165° C.

11. The method of claim 9, wherein the second temperature is substantially 250° C.

12. The method of claim 9, wherein the first and the second dry strips are performed in a C₂F₆ and O₂ gas mixture.

13. The method of claim 12, wherein the C₂F₆ and O₂ gas mixture has a substantially 2% ratio.

14. The method of claim 9, wherein the first and the second dry strips are performed by plasma oxidizing an inserted gas to remove photoresist from the semiconductor wafer without substrate peeling.

15. A method to dry strip a semiconductor wafer, comprising:
subjecting the semiconductor wafer to a first dry strip at a first temperature in a chamber to reduce thermal stress between photoresist on the wafer and the wafer; and,
subjecting the semiconductor wafer to a second dry strip at a second temperature in the chamber to complete the dry strip without substrate peeling of the wafer, the second temperature higher than the first temperature.

16. The method of claim 15, wherein the first dry strip is performed in a pin up position within the chamber, and the second dry strip is performed in a pin down position within the chamber.

17. The method of claim 16, wherein the chamber comprises a heater block and a plurality of pins vertically movable therewithin, such that the pin up position within the chamber is where the semiconductor wafer rests upon ends of the pins above the heater block, and such that the pin down position within the chamber is where the semiconductor wafer rests upon at least the heater block.

18. The method of claim 15, wherein the first temperature is substantially 165° C., and the second temperature is substantially 250° C.

19. The method of claim 15, wherein the first and the second dry strips are performed in a C₂F₆ and O₂ gas mixture.

20. The method of claim 19, wherein the C₂F₆ and O₂ gas mixture has a substantially 2% ratio.
